(19) United States
(12) Patent Application Publication
(10) Pub. No.: US 2014/0138047 A1
(43) Pub. Date: May 22, 2014

(54) AIRSTREAM VECTORING ACCESS FLOOR PANEL

(71) Applicants: Walter E. Phelps, Merrimack, NH (US); John D. Owen, New Ipswich, NH (US); Venkata Naga Poornima Mynampati, Milford, NH (US)

(72) Inventors: Walter E. Phelps, Merrimack, NH (US); John D. Owen, New Ipswich, NH (US); Venkata Naga Poornima Mynampati, Milford, NH (US)

(73) Assignee: Degree Controls, Inc., Milford, NH (US)

(21) Appl. No.: 14/084,367

(22) Filed: Nov. 19, 2013

Related U.S. Application Data
(60) Provisional application No. 61/728,620, filed on Nov. 20, 2012.

(51) Int. Cl. H05K 7/20; F28F 13/06

(52) U.S. Cl. CPC H05K 7/20745; F28F 13/06
USPC 165/57; 454/290; 454/325

(57) ABSTRACT

An airflow vectoring access floor panel for raised floor data centers has an access panel and a plurality of airflow deflectors. Each of the plurality of airflow deflectors can be independently rotated to affect the directionality of the emanating airstreams. The airstreams can be diverged, converged or impinged in any direction to intersect with the intakes of IT racks within a data center. A fan assembly can be placed underneath the unit to increase the volume of airflow and thus the number and heat load of the IT racks that can be supplied by a single access panel. The airflow deflectors may be rotated manually or by electromechanical drives.

### RELATED APPLICATIONS

This application claims the benefit of U.S. Provisional Application No. 61/728,620, filed Nov. 20, 2012, entitled “Airstream Vectoring Access Floor Panel,” which is incorporated herein by reference in its entirety.

### TECHNICAL FIELD

This disclosure relates to an airflow distribution method and apparatus for directing air from a raised access floor plenum to an above floor area in a data center. In an embodiment, the disclosure relates to an access floor panel having a plurality of diffusers that can be rotated independently of each other by manual or electromechanical means to diverge, converge or impinge airflow streams. The resulting and available airflow streams allow a single point of delivery to precisely vector airflow streams to a larger area. A fan assembly may be used underneath the access floor panel to increase available airflow from the apparatus.

### BACKGROUND

Many data centers use a pressurized underfloor plenum to deliver cooling air into the space that needs to be thermally maintained. This pressurized underfloor plenum is created by an array of square access floor panels typically, but not always, two feet by two feet, and is supported by an array of pedestals on a concrete or other type of subfloor to create a raised access floor plenum. This raised access floor spans the entire area of the space to be supplied with cooling air. Pressure to the underfloor plenum is provided by heating, ventilation, and air conditioning (HVAC) equipment, usually multiple units with large blowers, which supply cooling air to the underfloor plenum. This cooling air in the underfloor plenum is then distributed to information technology (IT) racks located in various and disparate locations on top of the raised access floor. To allow cooling air delivery from the pressurized plenum to IT rack intakes, a subset of the access floor panels are perforated, and have an open grate, a single square, a rectangular or round diffuser, or simply a hole. Cooling air from these perforated access floor panels is delivered to the front of the IT racks. The cooling air is then drawn in by fans located in electronics in the IT racks. The cooling air is heated by the electronics, and then ejected from the back of the IT racks. The heated air is drawn back into the HVAC equipment's return air intake to be cooled and resupplied to the underfloor plenum in a continuous cycle.

The IT racks in the data center can be laid out in many different floor plan configurations, and each configuration can require many hundreds or even more than one thousand cubic feet per minute (CFM) of cooling air to maintain safe operating conditions. The IT racks are most typically arranged in rows. Higher heat load racks can require their own dedicated perforated or other type of access panel opening to provide enough cooling. This results in rows of racks, many with their own perforated or other type of panel opening being placed side by side in a data center. Underfloor pressure, which determines the CFM that can be delivered by a single or group of perforated or other type of access panel openings, is seldom evenly distributed due to obstructions under the floor, HVAC unit placement, or a localized high concentration of IT loads consuming cooling air. As such, the percentage opening of the access panel chosen at each rack needs to be selected to deliver the proper amount of cooling air to the IT racks to prevent overheating. In some cases, there will not be enough localized underfloor plenum pressure to deliver the required CFM through a perforated or other type of access panel opening to cool the IT rack or racks. In this case, booster fans can be used under the raised access floor air distribution panels to increase localized pressure using far less total fan energy than if additional large HVAC blowers were used to increase overall underfloor plenum pressure.

Data centers use tremendous amounts of electrical energy to cool the IT racks housed within them, in most cases equaling the IT electricity usage. The cube law of fans states that to double flow or pressure, eight times the amount of energy is needed. Thus by utilizing much smaller booster fans that do not need to overcome static pressure in the underfloor, a more energy efficient airflow distribution method can be achieved. There is a cost to implementing booster fans which can be prohibitive if they are needed in great numbers.

Existing access floor air distribution panels for data centers, whether perforated, grate style, or with rectangular or circular diffusers, distribute air in a single vertical or angled plane with respect to the raised floor and IT racks. For example, U.S. Patent Publication US 2012 0060429 A1 and U.S. Pat. Nos. 8,511,022 B2, 7,823 340 B2, 8,099 912 B2, and D636,099 describe embodiments of such access floor distribution panels that distribute air in a single vertical plume or plane with respect to the raised floor and IT racks. U.S. Patent Publication Nos. U.S. 2009 0293518 A1 and US 2008 0108296 A1 describe embodiments of fan assisted access floor distribution panels that can deliver air at variable or fixed angles, however all in the same plane with respect to the raised floor and IT racks.

In all these references, the airflow distribution coverage from individual access floor air distribution panels of any style, with or without a booster fan, is limited to an IT rack adjacent to the perforated panel or other opening, thus requiring individual access floor air distribution panels for nearly every IT rack. With such a distribution system, if booster fans are considered as a means to allow savings in total HVAC fan energy, a great number of booster fans would be needed at some cost.

Also variations in plenum pressure from one area to another area cannot be used (i.e., shared) to assist in providing cooling air to an IT rack that is near a boundary between high and low plenum pressure. One very common example in data centers is near HVAC units where plenum pressure in the first six feet from the front of the HVAC unit is low or negative due to high underfloor air velocity caused by the venturi effect. Plenum pressure quickly builds to a high pressure at eight feet and beyond. Most data centers cannot waste expensive floor space and tend to place IT racks too close to HVAC units. Moving existing IT racks, after they have been installed and running, with equipment and communications, is extremely expensive. However many data center operators will not know about such cooling problems until after the IT rack is operational. In present practice, data center operators are either forced to not install IT racks, to lightly load IT racks close to HVAC units, or to suffer overheating conditions due to low plenum pressure and low cooling airflow available at those locations.

### SUMMARY

In view of the above it is desirable to have an airflow distribution method that can serve a larger number of IT racks from a single raised access floor distribution panel.

The present disclosure provides a method for vectoring airstreams from a single raised access floor air distribution panel in a flexible and field adjustable manner to allow coverage to a plurality of IT racks. In the case of using booster fans, a single fan can provide cooling air to many IT racks, thereby lowering total equipment costs for the fans while saving HVAC fan energy. In the case of underfloor plenum pressure variation, a single distribution point in a high pressure location could serve nearby racks that are positioned over a low plenum pressure area.

In one embodiment, a plurality of fixed angle circular diffusers is placed into a specially designed raised access floor panel designed to withstand static and rolling loads encountered in data centers. These fixed diffusers have an angle of inclination with respect to the vertical axis of between 36° and 70°. All the fixed diffusers within the single raised access floor panel can have the same or different angles of between 36° and 70°. Each of these fixed angle circular diffusers can be rotated independently of each other to diverge, converge or impinge airflow streams to affect the delivery of cooling air from a raised access floor plenum to the IT racks above.

In a further embodiment, the plurality of circular diffusers are able to have their angle of inclination adjusted to any angle with respect to the vertical axis of between 0° and 90°. In this instance, 0° is fully open with no directionality of airstream, and 90° is fully closed. Angles in between allow adjustment of the angle of the airstream emanating from the diffuser.

In a further embodiment, the plurality of fixed angle diffusers is rectangular or square. These fixed diffusers have an angle of inclination with respect to the vertical axis of between 36° and 70°. All the fixed diffusers within the single raised access floor panel can have the same or different angles of between 36° and 70°. Each of these fixed angle rectangular or square diffusers can be lifted out of the support frame, rotated independently of each other in 90° increments, and reinserted to diverge, converge, or impinge airflow streams to affect the delivery of cooling air from a raised access floor plenum to the IT racks above.

In another embodiment, as described in the previous paragraph, the plurality of rectangular or square diffusers can have their angle of inclination adjusted to any angle with respect to the vertical axis of between 0° and 90°. In this instance 0° is fully open with no directionality of airstream, and 90° is fully closed. Angles in between allow adjustment of the angle of the airstream emanating from the diffuser.

In another embodiment, round diffusers can be rotated by an electromechanically actuated rotary drive mechanism to affect the desired coverage area.

In another embodiment, any of the previous embodiments can have a single fan or array of fans placed beneath them to boost airflow delivery beyond what can be obtained with available underfloor plenum pressure alone. These fans can be fixed or variable speed as required by the application.

### BRIEF DESCRIPTION OF THE DRAWINGS

Embodiments are illustrated by way of the following example drawings.

FIG. 1 is a top perspective view of an airstream vectoring access floor panel according to an embodiment.

FIG. 2 is a side view of the embodiment of FIG. 1.

FIG. 3 is a side view of component 14A through 1411 of FIG. 1, FIG. 2, and FIG. 7.

FIG. 4 is a cross section of an embodiment of FIG. 3 showing airflow paths.

FIG. 5 is a cross section of an alternate embodiment of FIG. 3 showing airflow paths.

FIG. 6 is a cross section of an alternate embodiment of FIG. 3 showing airflow paths.

FIGS. 7A, 7B, 7C, and 7D illustrate alternate embodiments of the embodiment of FIG. 1.

FIG. 8 is a top perspective view of a further embodiment.

FIG. 9 is a cross section view of the embodiment of FIG. 8.

FIG. 10 is a perspective view of component 34A through 34D of FIG. 8 and FIG. 9.

FIG. 11 is a cross section of an embodiment of FIG. 10 showing airflow paths.

FIG. 12 is a cross section of an alternate embodiment of FIG. 10 showing airflow paths.

FIG. 13 is a cross section of an alternate embodiment of FIG. 10 showing airflow paths.

FIGS. 14A, 14B, and 14C illustrate alternate embodiments of FIG. 1 and FIG. 9.

FIG. 15 is a fan-assisted, vectored airflow panel according to a further embodiment.

FIG. 16 is an electro-mechanically adjusted vectored airflow panel according to a further embodiment.

FIG. 17 is a schematic view illustrating the use of an embodiment of FIG. 1 in a data center.

FIG. 18 is a flow chart for fan control according to the embodiment of FIG. 15.

### DETAILED DESCRIPTION

For illustrative purposes and ease of understanding, the principles of the present disclosure are described by referring mainly to an embodiment thereof. In the following description, numerous specific details are set forth in order to provide a thorough understanding of the disclosure and its embodiments. It will be apparent to one skilled in the art however that the embodiments may be practiced without limitation to the specific details described herein. Common and well known methods of construction have not been described in specific detail so as not to unnecessarily obscure the understanding of the present embodiments.

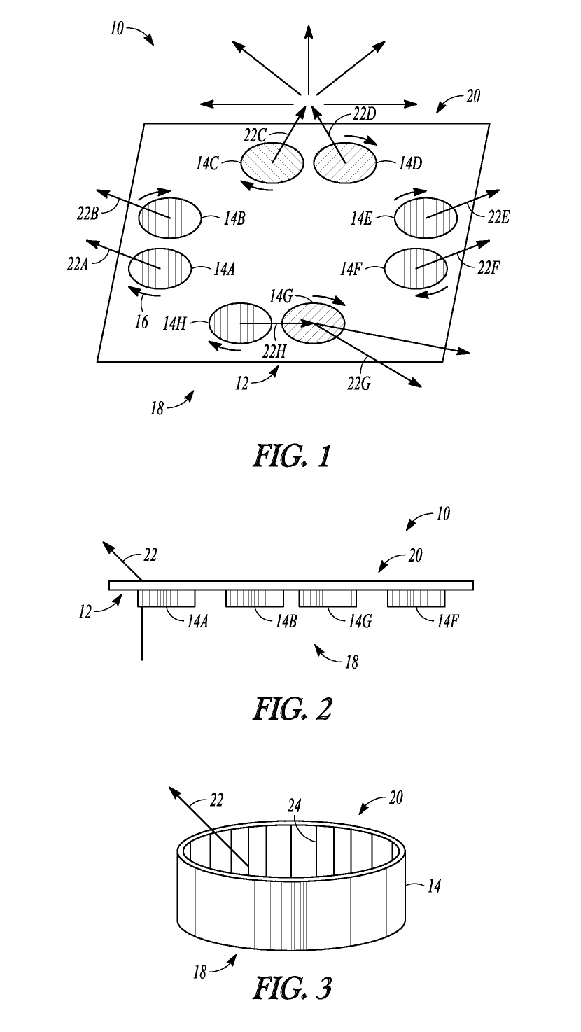

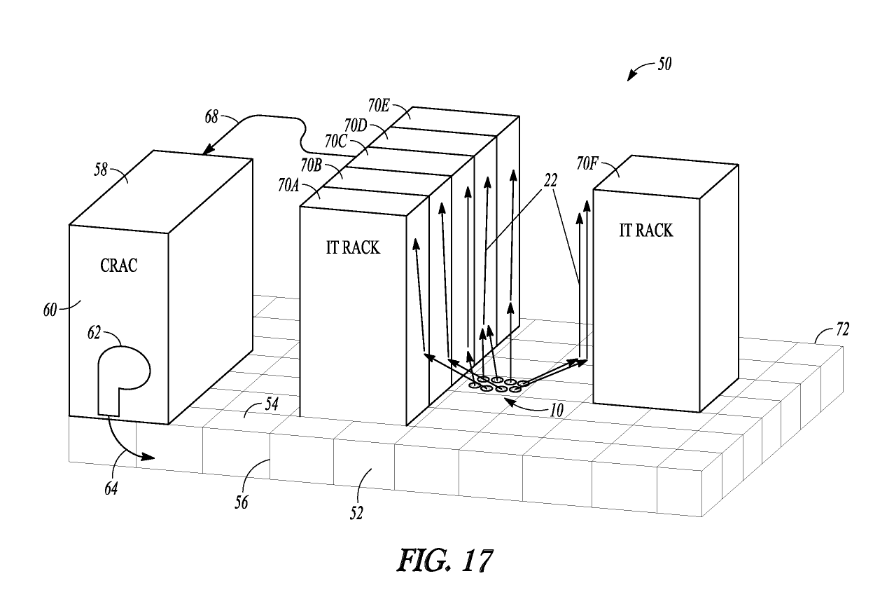

A simplified schematic of a data center 50 is illustrated in FIG. 17 to explain the application of an embodiment of the current disclosure 10 (See FIG. 1). The data center contains a raised access floor 72 which is constructed from a plurality of solid or perforated raised access floor panels 54 supported at each corner by stanchions 56. The raised floor 72 extends in all directions to the walls of the computer room 50 creating a sealed raised access floor plenum 52. A computer room air conditioner (CRAC) 58 is placed on the top of the raised access floor 72. Within the CRAC 58 is a blower unit 62 to draw warm air 68 from IT racks 70A through 70E through a cooling coil 60. Cooled air 64 is introduced into the raised access floor plenum 52 through openings in the raised access floor 72 under CRAC unit 58. Cooling air 64 is then delivered under pressure to the raised access floor plenum 52. A plurality of power and communications cables (not shown), plus pipes (not shown) for carrying cooling fluid, may be located in various locations in the raised access floor plenum 52 and restrict delivery of cooling air 64 to some areas of the raised access floor 72. It should be understood that the simplified schematic illustration of a data center 50 can contain any number of CRACs 58 and IT racks 70A through 70F as well as other equipment. The simplified illustration in FIG. 17 is for understanding of the invention, and is not intended to limit the present invention in any respect as to the contents of any given data center 50.

The IT racks 70A through 70F each contain a plurality of electronic equipment sets, such as, but not limited to, servers, disk drive arrays, and communications equipment. The electronic equipment within the IT racks 70A through 70F can draw significant electrical power. The power drawn by the electronic equipment in the IT racks 70A through 70F is converted into processing power which, other than spinning disk drive platters, performs no mechanical work. As such nearly all the electrical power consumed by electronic equipment in IT racks 70A through 70F is converted directly into heat by said electronic equipment. This electronic equipment housed in IT racks 70A through 70F must be kept cool to operate reliably. The typical operating specification for said electronic equipment requires intake air into the equipment to be below 80.6 degrees Fahrenheit. Without a CRAC cooling system 58 to remove heat outside data center 50, the air temperature within data center 50 would quickly rise to dangerous levels for the electronic equipment. The CRAC cooling system 58 in the data center 50 provides a method to take heated air 68 from the IT racks 70A through 70F, extract the heat outside data center 50 via cooling coil 60 and it's associated heat rejection equipment, and reintroduce cooled air 64 to the raised access floor plenum 52 using blower 62.

The cooled air is then delivered back to the IT racks 70A through 70F via one embodiment of the present invention 10, which is a vectored raised access floor distribution panel. The present invention 10 has its individual airflow deflectors 14A through 1411 (See FIG. 1) adjusted to a fixed rotation angle 16 (See FIG. 1.) to deliver cooling air flows 22A through 2211 (See FIG. 1) in the proper directions to intersect with the inlet sides of each of the IT racks 70A through 70F.

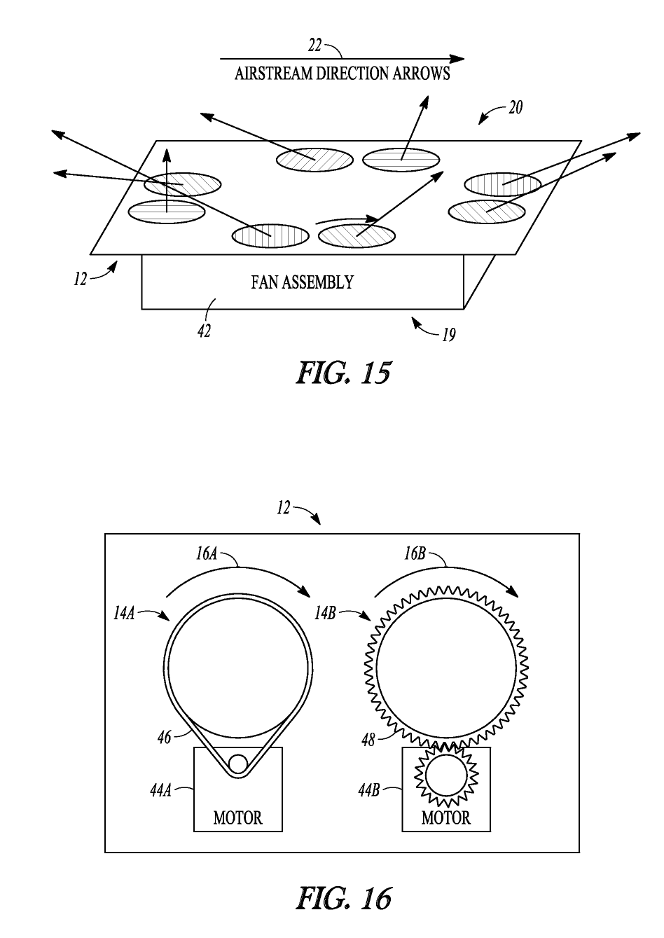

Due to the proximity of CRAC 58, underfloor obstructions (not shown) in the raised access floor plenum 52 and potential high electrical and heat loads in IT racks 70A through 70F, there may be insufficient pressure in the raised access floor plenum 52 to allow adequate cooling airflow 22 to each of the IT racks 70A through 70F. Another embodiment (See FIG. 15) has a fan assembly 19 (See FIG. 15) attached to increase cooling airflow 22 to the IT racks 70A through 70F. The fan assembly 19 (See FIG. 15) may be controlled by thermostatic sensors on IT racks 70A through 70F to modulate airflow 22 volume or may be set to a fixed airflow 22 volume.

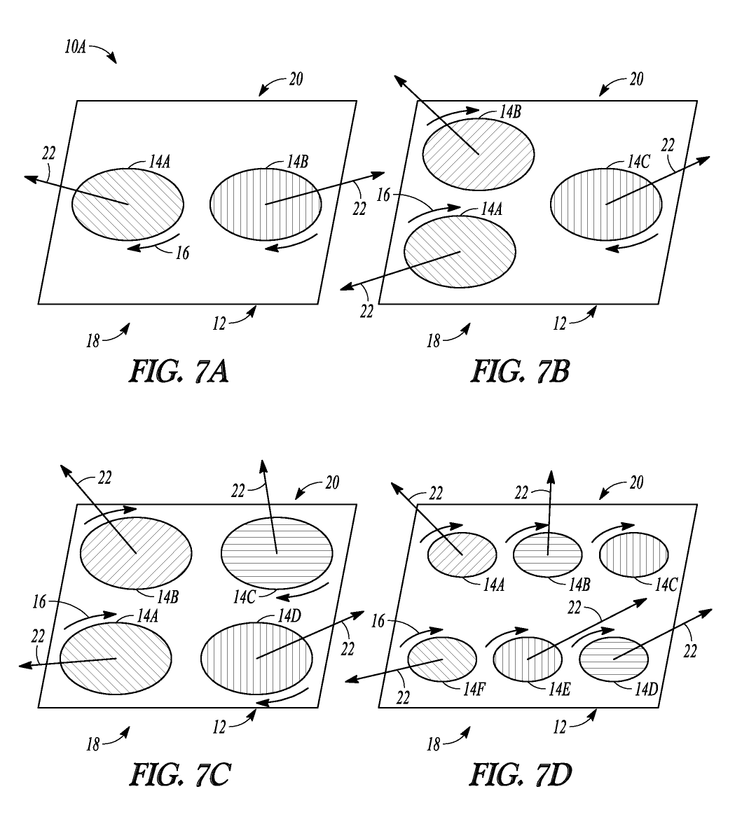

FIG. 1 illustrates a perspective view of an embodiment 10. The embodiment, an airstream vectoring access floor panel, includes a raised access floor panel 12, designed to withstand typical static and rolling loads in a data center and fitted with a plurality of circular airflow deflectors 14A through 1411. Each of the circular airflow deflectors 14A through 1411 can be rotated independently of each other as illustrated by arrow 16 associated with 14A. To simplify the drawing in FIG. 1, only the rotation arrow 16 associated with 14A is labeled. However, all instances of 14A through 1411 can be independently rotated in the same manner as 14A as illustrated by rotation arrow 16. The embodiment has an upstream side 18 and a down stream side 20 with respect to airflow 22A through 2211 emanating from the airstream vectoring access floor panel 10. The rotational position 16 of the circular airflow deflectors 14A through 1411 allow airflow streams 22A through 2211 to be independently directed as desired. An example of airstream directionality is shown in FIG. 1. Circular airflow deflectors 14A through 14F have been rotated in the illustration in FIG. 1 to diverge airstreams outward as in 22A, 22B, 22E, and 22F, to converge airstreams as in 22C and 22D, or impinge air streams as in 22G and 22H. The illustration in FIG. 1 in no way restricts the allowable rotational adjustments possible with the circular airflow directors 14A through 14F in the current embodiment, and is for ease of understanding how the various rotational adjustments can be used to affect airstream coverage to a plurality of locations. The number and size of the circular airflow deflectors in the current embodiment can vary in other embodiments, (See FIGS. 7A, 7B, 7C, and 7D). The number of airflow deflectors in FIG. 1 is for illustrative purposes only, and in no way restricts the size and number of circular airflow deflectors that can be used in any of the other embodiments.

FIG. 2 illustrates a side view of an embodiment 10 previously illustrated as a perspective view in FIG. 1. The raised access floor panel 12, designed to withstand typical static and rolling loads in a data center, has circular airflow deflectors 14A through 1411 inserted in a manner that allows rotation. In this illustration, only circular airflow deflectors 14A, 14H, 14G, and 14F are visible. The remainder of the circular airflow deflectors is located directly behind the visible components. There is an upstream side 18 and a down stream side 20 with respect to airflow 22 through the embodiment. The number and size of the circular airflow deflectors in the current embodiment can vary in other embodiments (See FIGS. 7A, 7B, 7C, and 7D). FIG. 2 is for illustrative purposes only, and in no way restricts the size and number of circular airflow deflectors that can be used in any of the other embodiments. Those skilled in the art will realize the exact outer dimensions and mounting surface dimensions of the of the raised access floor panel 12 may be specific to the data center 50 (See FIG. 17). The illustration of the raised access floor panel 12 in FIG. 2 in no way restricts the allowable outer or mounting surface dimensions or shapes in the present invention.

FIG. 3 illustrates a perspective view of a circular airflow deflector 14 used in various embodiments. There is an upstream side 18 and a down stream side 20 with respect to airflow 22 through the circular airflow deflector 14. The top of the circular airflow deflector 14 has a plurality of ribs, vanes or support bars 24 that allow the airstream 22 to pass through, thereby permitting physical loads to be applied such as people walking over circular airflow deflector 14 or equipment to be rolled across circular airflow deflector 14. The illustration in FIG. 3 is for understanding of the present invention 10, and in no way restricts the height or outer diameter of the circular airflow deflector(s) 14 or the number, relative position or width of ribs, vanes, and/or support bars 24.

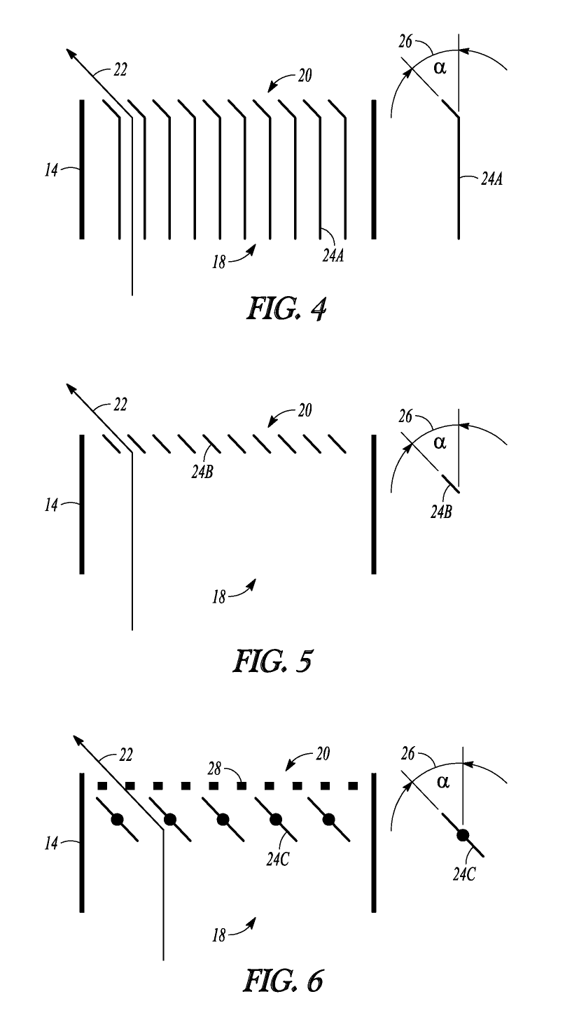

FIG. 4 illustrates a cross section view of an embodiment of the circular airflow deflector 14 described in FIG. 3 and used in various embodiments. There is an upstream side 18 and a down stream side 20 with respect to airflow 22 through the circular airflow deflector 14. Airflow 22 induced via pressure or by fans from the raised access floor 72 (See FIG. 17) is introduced to the upstream side 18 and flows to the downstream side 20. A plurality of guide vanes as in 24A guide the airstream out at an angle 26 of between 36 and 70 degrees, which has been shown to be the range of angles that allows effective airstream delivery to a plurality of IT racks as illustrated by 70A through 70F (See FIG. 17) in a data center 50 (See FIG. 17). The chosen angle 26 of between 36 and 70 degrees can be selected to be different for each or any of the circular airflow deflectors 14 or guide vanes 24A therein in any of the embodiments of the present disclosure that use a circular airflow deflector 14. For example, an angle of 38 degrees can be selected for some guide vanes 24A, and an angle of 60 degrees can be selected for others on the same circular airflow deflector 14. Alternately, all guide vanes 24A within a single circular airflow deflector 14 can be of the same angle 26, and different angle styles of circular airflow deflectors can be installed in a single airstream vectoring access floor panel 12. This will allow airstream delivery 22 to be customized for the particular application. The illustration shown in FIG. 4 is for understanding of the current embodiment, and in no way restricts the number, relative position, thickness or shape of the guide vanes as in 24A used in the circular airflow deflector 14 except that they provide an exit angle for airflow 22 of between 36 and 70 degrees as shown in angle 26.

FIG. 5 illustrates a cross section view of another embodiment of the circular airflow deflector 14 described in FIG. 3 and used in various embodiments of the present disclosure. The circular airflow deflector shown in FIG. 5 is identical in function and application as the previous FIG. 4 design, with the exception that the vertical portions of the guide vanes 24B have been removed. The illustration shown in FIG. 5 is for understanding of the current embodiment, and in no way restricts the number, relative position, thickness, or shape of the guide vanes as in 24B used in the circular airflow deflector 14 except that they provide an exit angle for airflow 22 of between 36 and 70 degrees as shown in angle 26.

FIG. 6 illustrates a cross section view of another embodiment of the circular airflow deflector 14 described in FIG. 3 and used in various embodiments of the present disclosure. There is an upstream side 18 and a down stream side 20 with respect to airflow 22 through the circular airflow deflector 14. Airflow 22 induced via pressure or by fans from the raised access floor 72 (See FIG. 17) is introduced to the upstream side 18 and flows to the downstream side 20. A plurality of adjustable diffuser vanes, as in 24C, guides the airstream 22 out at an angle 26. The plurality of adjustable diffuser vanes, as in 24C, can be linked together or individually adjusted to form an angle 26 of between 0 and 90 degrees. A plurality of load support bars 28 supports physical loads to be applied such as people walking over circular airflow deflector 14 or equipment to be rolled across circular airflow deflector 14. The illustration shown in FIG. 6 is for understanding of the current embodiment, and in no way restricts the number, relative position, thickness, or construction of the adjustable diffuser vanes as in 24C or load support bars 28 used in the circular airflow deflector 14.

FIGS. 7A, 7B, 7C, and 7D illustrate perspective views of other various embodiments of the present disclosure, that is, an airstream vectoring access floor panel 10A. A plurality of circular airflow deflectors as illustrated by 14A through 14F may be used in a variety of quantities and configurations. The illustration shown in FIG. 7 is for understanding of possible embodiments of the present disclosure, and in no way restricts the number or placement of the plurality of circular airflow deflectors 14A through 14F into the airstream vectoring access floor panel 10A.

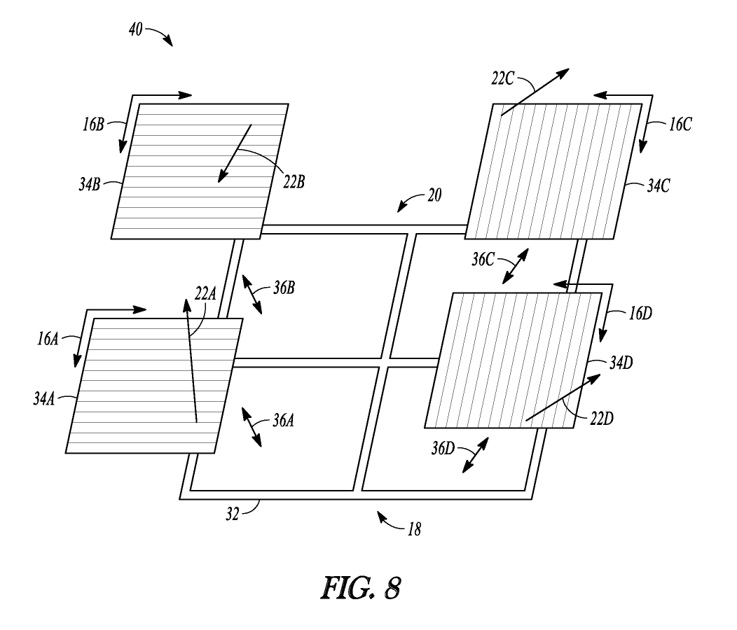

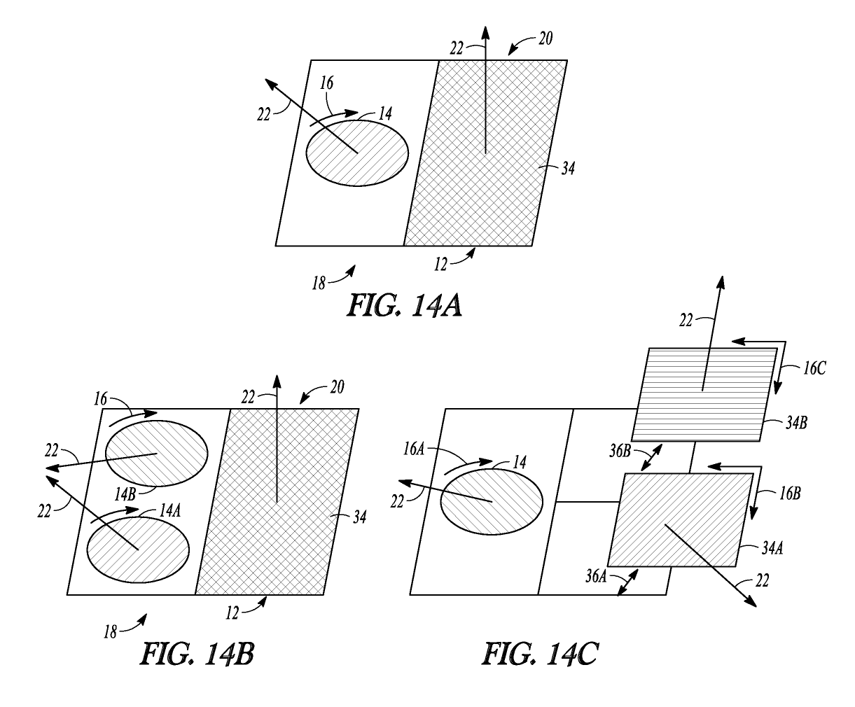

FIG. 8 shows a perspective view of another embodiment 40 of the present disclosure, an airstream vectoring access floor panel using a plurality of rectangular airflow deflectors 34A through 34D. A support frame 32 is constructed with perimeter and cross support bars to support the rectangular airflow deflectors 34A through 34D. The support frame 32 is also designed to withstand typical static and rolling loads in a data center. There is an upstream side 18 and a down stream side 20 with respect to airflow 22A through 22D emanating from the airstream vectoring access floor panel 40 through the rectangular airflow deflectors 34A through 34D. The rectangular airflow deflectors 34A through 34D can be individually lifted as illustrated by arrows 36A through 36D and rotated as illustrated by arrows 16A through 16D and then reinserted into support frame 32 to be independently directed as desired. An example of airstream directionality is shown in FIG. 8. Rectangular airflow deflectors 34A through 34D have been rotated in the illustration to impinge airstreams as in 22A and 22B, or to diffuse airstreams as in 22C and 22D. The illustration in FIG. 8 in no way restricts the allowable rotational adjustments possible with the rectangular airflow deflectors 34A through 34D in this embodiment 40, or any other embodiments thereof, and is for ease of understanding how the various rotational adjustments can be used to affect airstream coverage to a plurality of locations. The number and size of the rectangular airflow deflectors 34A through 34D in the present disclosure can vary in other embodiments (See FIG. 14). FIG. 8 is for illustrative purposes only, and in no way restricts the size and number of rotatable rectangular airflow deflectors 34A through 34D that can be used in any of the other embodiments thereof.

In another embodiment, the geometric shape of the plurality of airflow deflectors may be triangular, pentagonal, hexagonal, octagonal, oval, or any other geometric shape with the only restriction that they can be removed, rotated and reinserted into different rotational angles in the support frame 32 or access floor panel 12 (See FIGS. 1 and 2) to affect airstream direction.

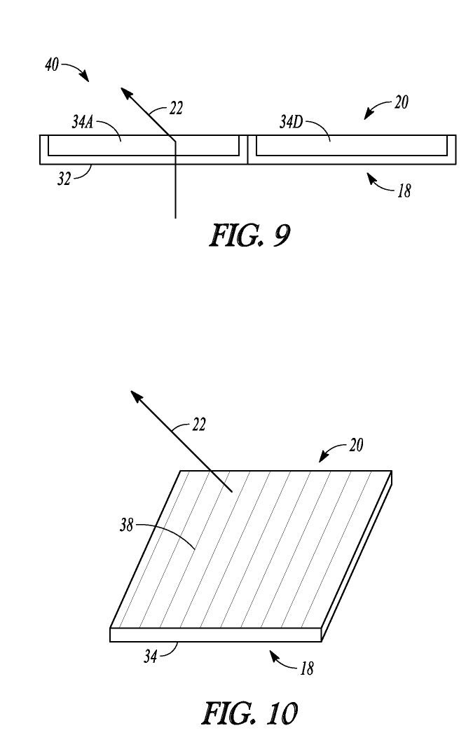

FIG. 9 illustrates a cross section view of the embodiment 40 previously illustrated as a perspective view in FIG. 8. The support frame 32, designed to withstand typical static and rolling loads in a data center has rectangular airflow deflectors 34A through 34D inserted in a manner that allows rotation in 90° increments by lifting, rotating and reinserting into the support frame 32. In this illustration, only rectangular airflow deflectors 34A, 34D are visible. The remainders of the rectangular aiflow deflectors are located directly behind the visible components. There is an upstream side 18 and a down stream side 20 with respect to airflow 22 through the embodiment. The number and size of the rectangular airflow deflectors in the embodiment can vary in other embodiments. FIG. 9 is for illustrative purposes only and in no way restricts the size and number of rectangular airflow deflectors that can be used in any of the other embodiments. Those skilled in the art will realize the exact outer dimensions and mounting surface dimensions of the of the support frame 32 may be specific to the data center 50 (See FIG. 17). The illustration of the support frame 32 in FIG. 9 in no way restricts the allowable outer or mounting surface dimensions or shapes in the present invention.

FIG. 10 illustrates a perspective view of a rectangular airflow deflector 34 used in various embodiments of the current invention. There is an upstream side 18 and a down stream side 20 with respect to airflow 22 through the rectangular airflow deflector 34. The top of the circular airflow deflector 34 has a plurality of ribs, vanes, or support bars 38 that allow the airstream 22 to pass through and allow physical loads to be applied such as people walking over circular airflow deflector 34 or equipment to be rolled across circular airflow deflector 34. The illustration in FIG. 10 is for understanding of the embodiment 40 and in no way restricts the height or outer dimensions of the rectangular airflow deflector(s) 34, or the number, relative position, or width of ribs, vanes, and/or support bars 38.

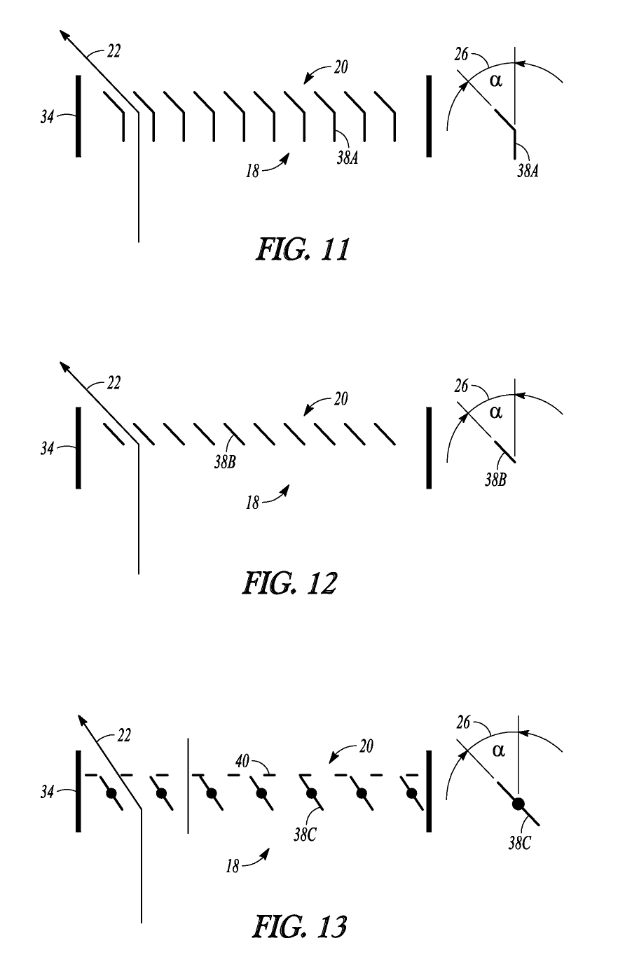

FIG. 11 illustrates a cross section view of one embodiment of the rectangular airflow deflector 34 described in FIG. 10 and used in various embodiments. There is an upstream side 18 and a down stream side 20 with respect to airflow 22 through the rectangular airflow deflector 34. Airflow 22 induced via pressure or by fans from the raised access floor 72 (See FIG. 17) is introduced to the upstream side 18 and flows to the downstream side 20. A plurality of guide vanes as in 38A guide the airstream out at an angle 26 of between 36 and 70 degrees which has been shown to be the range of angles that allows effective airstream delivery to a plurality of IT racks as illustrated by 70A through 70F (See FIG. 17) in a data center 50 (See FIG. 17). The chosen angle 26 of between 36 and 70 degrees can be selected to be different for each or any of the rectangular airflow deflectors 34 or guide vanes 38A therein in any of the embodiments of the present invention that use a rectangular airflow deflector 34. For example, an angle of 36 degrees can be selected for some guide vanes 38A and an angle of 60 degrees can be selected for others on the same rectangular airflow deflector 34. Alternately, all guide vanes 38A within a single rectangular airflow deflector 34 can be of the same angle 26, and different angle styles of rectangular airflow deflectors can be installed in a single airstream vectoring access floor panel 34. This will allow airstream delivery 22 to be customized for the particular application. The illustration shown in FIG. 11 is for understanding of the present invention and in no way restricts the number, relative position, thickness or shape of the guide vanes as in 38A used in the rectangular airflow deflector 34 except that they provide an exit angle for airflow 22 of between 36 and 70 degrees as shown in angle 26.

FIG. 12 illustrates a cross section view of another embodiment of the rectangular airflow deflector 34 described in FIG. 10 and used in various embodiments. The rectangular airflow deflector shown in FIG. 12 is identical in function and application as the previous FIG. 11 design with the exception that the vertical portions of the guide vanes 38B have been removed. The illustration shown in FIG. 12 is for understanding of the present invention and in no way restricts the number, relative position, thickness or shape of the guide vanes as in 38B used in the rectangular airflow deflector 34 except that they provide an exit angle for airflow 22 of between 36 and 70 degrees as shown in angle 26.

FIG. 13 illustrates a cross section view of another embodiment of the rectangular airflow deflector 34 described in FIG. 10 and used in various embodiments. There is an upstream side 18 and a down stream side 20 with respect to airflow 22 through the rectangular airflow deflector 34. Airflow 22 induced via pressure or by fans from the raised access floor 72 (See FIG. 17) is introduced to the upstream side 18 and flows to the downstream side 20. A plurality of adjustable diffuser vanes as in 38C, guide the airstream 22 out at an angle 26. The plurality of adjustable diffuser vanes as in 38C can be linked together or individually adjusted to form an angle 26 of between 0 and 90 degrees. A plurality of load support bars 40 support physical loads to be applied such as people walking over rectangular airflow deflector 34 or equipment to be rolled across rectangular airflow deflector 34. The illustration shown in FIG. 13 is for understanding of the present invention and in no way restricts the number, relative position, thickness or construction of the adjustable diffuser vanes as in 38C or load support bars 40 used in the rectangular airflow deflector 34.

FIGS. 14A, 14B, and 14C illustrate perspective views of other various embodiments of an airstream vectoring access floor panel. A plurality of airflow deflectors of any of the previously defined shapes, circular, rectangular, or other geometric shape may be used in a variety of quantities and configurations; with the only restriction that at least one airflow deflector must be rotatable to affect airflow. The illustrations shown in FIGS. 14A, 14B, and 14C are for understanding of possible embodiments of the present disclosure and in no way restricts the number or placement of the plurality of airflow deflectors into any embodiment.

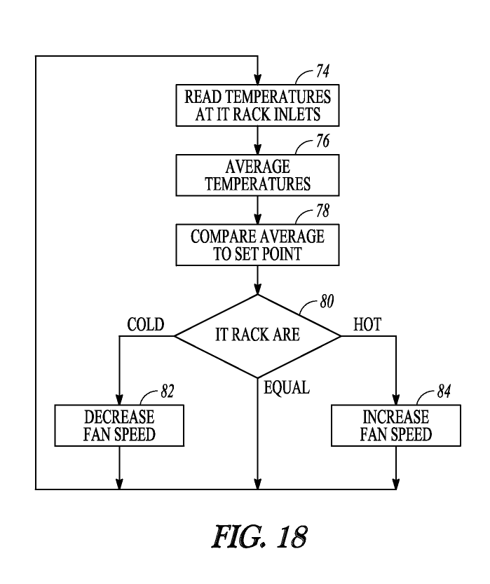

FIG. 15 illustrates the attachment of a fan assembly 42 to the upstream side 18 in any of the previous embodiments of an airstream vectoring access floor panel. The purpose of the fan assembly is to increase the volume and reach of the airstreams 22 emanating from an embodiment. The fan assembly 42 may contain a single fan or a plurality of fans. The fans housed in fan assembly 42 may be run at a fixed speed or controlled by temperature sensors (not shown) that are on or in IT Racks 70A-70F (See FIG. 17) in a program sequence manner as illustrated in FIG. 18. The fan speed(s) may be controlled as a group, or individual fans within in the fan assembly 42 may be coupled to individual sensors thus controlling the volume and strength of the airstreams independently.

FIG. 16 illustrates an embodiment where the plurality of airflow deflectors 14A and 14B may have their rotational positions 16A and 16B adjusted by an electromechanical or electromagnetic device 44A and 44B. The drive mechanism for the airflow deflectors may be friction 46, geared 48, or electromagnetic (not shown). The view shown in FIG. 16 is of the upstream (or bottom) side 18 of the embodiment. The illustration shown in FIG. 16 is for understanding of an embodiment, and in no way restricts the number, relative position, or construction of the electromechanical or electromagnetic drives for the airflow deflectors.

FIG. 17 illustrates the use of the embodiment 10 in a data center 50, and is described in detail at the beginning of this section.

FIG. 18 illustrates a control algorithm that may be used in embodiments of the current invention that use a fan assembly 42 (See FIG. 15). Temperature sensors (not shown) are associated with fans 42 (See FIG. 15) and/or airflow deflectors 14 and 24 or pairs of airflow deflectors. Temperature sensors (not shown) in IT racks 70A through 70F (See FIG. 17) are read at 74, and if needed, are averaged at 76. The final reading is compared to a set point 78. A decision is then made at 80 to increase or decrease fan speed. If the rack temperature 76 is too hot, the fan speed is increased. If the rack temperature 76 is too cold, the fan speed is decreased. If the rack temperature 76 is equal to the set point, then the fan speed is not changed. This process repeats continuously.

What has been described and illustrated herein are embodiments of an airstream vectoring access floor panel as well as some possible variants thereof. The illustrations, descriptions, and terms used to describe the disclosed embodiments are set forth to aid in understanding, and are not meant as limitations to the embodiments. Those skilled in the art will recognize that other variants are possible within the scope of the disclosed embodiments, and that the embodiments are intended to be defined by the following claims—and their equivalents—which in all terms are meant in their broadest reasonable sense unless otherwise indicated.

The Abstract is provided to comply with 37 C.F.R. §1.72(b) and will allow the reader to quickly ascertain the nature and gist of the technical disclosure. It is submitted with the understanding that it will not be used to interpret or limit the scope or meaning of the claims.

1. An airflow vectoring access floor panel for use in a data center comprising:
a plurality of airflow deflectors;
wherein the airflow deflectors are set into the access floor panel such that the airflow deflectors are operable to independently rotate, thereby deflecting an airflow in a plurality of directions.

2. The access floor panel of claim 1,
wherein the airflow deflectors are operable to produce an angle of airflow deflection between 0 degrees and 90 degrees.

3. The access floor panel of claim 2, wherein the angle of airflow deflection is fixed between 36 degrees and 70 degrees.

4. The access floor panel of claim 1, wherein an individual airflow deflector comprises a plurality of vanes, wherein a first vane comprises a first angle of airflow deflection between 36 degrees and 70 degrees, wherein a second vane comprises a second angle of airflow deflection between 36 and 70 degrees, and wherein the first angle of airflow deflection is not equal to the second angle of airflow deflection.

5. The access floor panel of claim 4, wherein each of the vanes are capable of varying the angle of airflow deflection between 36 degrees and 70 degrees.

6. The access floor panel of claim 1, wherein the airflow deflectors are circular such that each airflow deflector can be rotated within the access floor panel, thereby affecting airflow direction.

7. The access floor panel of claim 6, wherein rotational positions of the circular airflow deflectors are controlled by an electromechanical device or an electromagnetic device.

8. The access floor panel of claim 1, wherein the airflow deflectors comprise a geometric shape such that the airflow deflectors are operable for removal from the access floor panel, rotation, and reinsertion into the access floor panel, the reinsertion resulting in an airflow direction that is different than an airflow direction prior to removal of the airflow deflectors from the access floor panel.

9. The access floor panel of claim 8, wherein the airflow deflectors are rectangular or square, and wherein the airflow deflectors are operable for removal from the access floor panel, rotation, and reinsertion into the access floor panel, the reinsertion resulting in the airflow direction that is different than the airflow direction prior to removal of the airflow deflectors from the access floor panel.

10. The access floor panel of claim 8, comprising a first airflow deflector comprising a first geometrical shape and a second airflow deflector comprising a second geometrical shape.

11. The access floor panel of claim 1, comprising a fan positioned adjacent to the airflow deflectors.

12. The access floor panel of claim 11, wherein a speed of the fan is controlled by a temperature sensor positioned in an information technology (IT) rack within the data center.

13. The access floor panel of claim 1, wherein the airflow deflectors are flush with a top surface of the access panel.

14. The access floor panel of claim 1, comprising load support bars such that the access floor panel and the airflow deflectors are capable of withstanding a transient or static load of at least 600 pounds.

15. An access floor panel comprising:
a plurality of airflow deflectors;
wherein the airflow deflectors are set into the access floor panel such that the airflow deflectors are operable to deflect an airflow in a plurality of directions.

16. The access floor panel of claim 15, wherein an individual airflow deflector comprises a plurality of vanes, wherein a first vane comprises a first angle of airflow deflection between 36 degrees and 70 degrees, wherein a second vane comprises a second angle of airflow deflection between 36 and 70 degrees, and wherein the first angle of airflow deflection is not equal to the second angle of airflow deflection.

17. The access floor panel of claim 15, wherein the airflow deflectors are circular such that each airflow deflector can be rotated within the access floor panel, thereby affecting the airflow direction; and wherein rotational positions of the circular airflow deflectors are controlled by an electromechanical device or an electromagnetic device.

18. The access floor panel of claim 15, wherein the airflow deflectors comprise a geometric shape such that the airflow deflectors are operable for removal from the access floor panel, rotation, and reinsertion into the access floor panel, the reinsertion resulting in an airflow direction that is different than an airflow direction prior to removal of the airflow deflectors from the access floor panel.

19. The access floor panel of claim 15, comprising a fan positioned adjacent to the airflow deflectors, wherein the fan comprises a speed variation control unit, and wherein the speed variation control unit is configured to be coupled to an information technology (IT) rack temperature sensor.

20. The access floor panel of claim 15, wherein the airflow deflectors are flush with a top surface of the access panel.
